(19) United States
(12) Patent Application Publication
(10) Pub. No.: US 2026/0122995 A1
(43) Pub. Date: Apr. 30, 2026

(54) SEMICONDUCTOR DEVICE

(71) Applicant: Nuvoton Technology Corporation Japan, Kyoto (JP)

(72) Inventors: Ryosuke OKAWA, Kyoto (JP); Hironao NAKAMURA, Kyoto (JP); Ryou KATO, Kyoto (JP); Eiji YASUDA, Kyoto (JP)

(21) Appl. No.: 19/420,024

(22) Filed: Dec. 15, 2025

Related U.S. Application Data
(63) Continuation of application No. PCT/JP2024/033909, filed on Sep. 24, 2024.
(60) Provisional application No. 63/585,092, filed on Sep. 25, 2023.

(51) Int. Cl. H10D 62/60; H10D 30/63

(52) U.S. Cl. CPC H10D 62/60; H10D 30/63

(57) ABSTRACT

A semiconductor device includes: a vertical metal-oxide semiconductor (MOS) transistor. In a plan view, an active region of the vertical MOS transistor includes unit cells repeatedly arranged within a plane of the active region, each unit cell is a hexagon having a perimeter defined along center positions of a width of a gate trench, in each unit cell, a shape of the body contact region exposed at the upper surface of a low-concentration impurity layer has a center that coincides with a center of the unit cell and rotational symmetry of 60° or less in a clockwise direction, and Lxm/3≤Lxr≤Lxm is satisfied, where Lxr μm denotes the width of the gate trench, and Lxm μm denotes a distance between parallel portions of the gate trench that face each other.

### CROSS REFERENCE TO RELATED APPLICATIONS

This is a continuation application of PCT International Patent Application No. PCT/JP2024/033909 filed on Sep. 24, 2024, designating the United States of America, which is based on and claims priority of U.S. Provisional Patent Application No. 63/585,092 filed on Sep. 25, 2023. The entire disclosures of the above-identified applications, including the specifications, drawings and claims are incorporated herein by reference in their entirety.

### FIELD

The present disclosure relates to a semiconductor device.

### BACKGROUND

A semiconductor device that includes a vertical Metal-Oxide-Semiconductor (MOS) transistor is known. Patent Literature (PTL) 1 discloses an example in which a gate trench of a vertical MOS transistor is located at positions corresponding to the perimeters of hexagons repeatedly arranged without spacing.

### CITATION LIST

### Patent Literature

PTL 1 Japanese Unexamined Patent Application Publication No. 2021-40105

### SUMMARY

### Technical Problem

In order to reduce the channel conduction resistance (On-Resistance) in a vertical MOS transistor, it is necessary to increase the total gate width. To increase the total gate width, it is effective to increase the area for providing a gate trench as much as possible. It is also effective to increase the density of providing a gate trench by reducing the width of the gate trench and the distance between portions of the gate trench.

With recent technologies, both the width of a gate trench and the distance between portions of the gate trench can be reduced to fine dimensions of 0.5 [μm] or less. For vertical MOS transistors having a structure including a gate trench, which has been reduced to such fine dimensions, there remains room for examining the optimal structure for effectively reducing channel conduction resistance.

Other problems and novel features will become apparent from the description given in the Specification and the accompanying drawings.

### Solution to Problem

A semiconductor device according to an aspect of the present disclosure includes: a vertical metal-oxide semiconductor (MOS) transistor that includes: a semiconductor substrate of a first conductivity type, the semiconductor substrate containing an impurity at a first concentration; a low-concentration impurity layer of the first conductivity type, the low-concentration impurity layer being provided above and in contact with the semiconductor substrate and containing an impurity at a second concentration lower than the first concentration of the impurity contained in the semiconductor substrate; a body region of a second conductivity type different from the first conductivity type, the body region being provided in the low-concentration impurity layer; a source region of the first conductivity type, the source region being provided in the body region; a body contact region of the second conductivity type, the body contact region being provided in the body region; a source electrode connected to the body contact region and the source region; a gate trench provided from an upper surface of the low-concentration impurity layer and penetrating through the body region to reach a depth up to a portion of the low-concentration impurity layer; a gate insulating film provided inside the gate trench; and a gate conductor provided above the gate insulating film and embedded inside the gate trench. In a plan view of the low-concentration impurity layer, an active region of the vertical MOS transistor includes unit cells repeatedly arranged within a plane of the active region, in the plan view, each of the unit cells is a hexagon having a perimeter defined along center positions of a width of the gate trench, in the plan view, in each of the unit cells, the source region in contact with the gate trench along an entire perimeter and the body contact region surrounded by the source region are exposed at the upper surface of the low-concentration impurity layer, in the plan view, in each of the unit cells, a shape of the body contact region exposed at the upper surface of the low-concentration impurity layer has a center that coincides with a center of the unit cell and rotational symmetry of 60[°] or less in a clockwise direction, in the plan view, in each of the unit cells, a shape of the source region exposed at the upper surface of the low-concentration impurity layer has a maximum width in a direction away from the gate trench, on a diagonal line connecting one corner of the unit cell and another corner opposite the one corner on a straight line across the center of the unit cell, and in the plan view, Lxm/3≤Lxr≤Lxm is satisfied, where Lxr [μm] denotes the width of the gate trench, and Lxm [μm] denotes a distance between parallel portions of the gate trench that face each other.

A semiconductor device according to an aspect of the present disclosure includes: a vertical metal-oxide semiconductor (MOS) transistor that includes: a semiconductor substrate of a first conductivity type, the semiconductor substrate containing an impurity at a first concentration; a low-concentration impurity layer of the first conductivity type, the low-concentration impurity layer being provided above and in contact with the semiconductor substrate and containing an impurity at a second concentration lower than the first concentration of the impurity contained in the semiconductor substrate; a body region of a second conductivity type different from the first conductivity type, the body region being provided in the low-concentration impurity layer; a source region of the first conductivity type, the source region being provided in the body region; a body contact region of the second conductivity type, the body contact region being provided in the body region; a source electrode connected to the body contact region and the source region; a gate trench provided from an upper surface of the low-concentration impurity layer and penetrating through the body region to reach a depth up to a portion of the low-concentration impurity layer; a gate insulating film provided inside the gate trench; and a gate conductor provided above the gate insulating film and embedded inside the gate trench. In a plan view of the low-concentration impurity layer, an active region of the vertical MOS transistor includes unit cells repeatedly arranged within a plane of the active region, in the plan view, each of the unit cells is a hexagon having a perimeter defined along center positions of a width of the gate trench, in the plan view, in each of the unit cells, the source region in contact with the gate trench along an entire perimeter and the body contact region surrounded by the source region are exposed at the upper surface of the low-concentration impurity layer, in the plan view, in each of the unit cells, in a shape of the body contact region exposed at the upper surface of the low-concentration impurity layer, on a diagonal line connecting one corner of the unit cell and another corner opposite the one corner on a straight line across a center of the unit cell, a distance between the one corner and the body contact region and a distance between the other corner and the body contact region differ from each other, a lower surface of the body contact region is located at a deeper position than a position of a lower surface of the source region, and a portion of the body contact region is directly under the source region.

### Advantageous Effects

According to a semiconductor device according to an aspect of the present disclosure, a semiconductor device that includes a vertical MOS transistor with reduced channel conduction resistance (On-Resistance) is provided.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A is a cross-sectional schematic diagram illustrating an example of a structure of a semiconductor device according to Embodiment 1.

FIG. 1B is a cross-sectional schematic diagram illustrating an example of a structure of the semiconductor device according to Embodiment 1.

FIG. 2A is a plan schematic diagram illustrating an example of a structure of the semiconductor device according to Embodiment 1.

FIG. 2B is a plan schematic diagram illustrating an example of a structure of the semiconductor device according to Embodiment 1.

FIG. 2C is a plan schematic diagram illustrating an example of a structure of the semiconductor device according to Embodiment 1.

FIG. 3 is a plan schematic diagram illustrating an example of a structure of the semiconductor device according to Embodiment 1.

FIG. 4 includes a plan schematic diagram and a cross-sectional schematic diagram each illustrating an example of a structure of a unit cell of the semiconductor device according to Embodiment 1.

FIG. 5 includes a plan schematic diagram and a cross-sectional schematic diagram each illustrating an example of a structure of a unit cell of the semiconductor device according to Variation 1 of Embodiment 1.

FIG. 6 is a graph illustrating a relation between the width of a gate trench in the plan view and a total gate width per unit area.

FIG. 7A is a plan schematic diagram illustrating an example of a structure of the semiconductor device according to Embodiment 1.

FIG. 7B is a plan schematic diagram illustrating an example of a structure of the semiconductor device according to Embodiment 1.

FIG. 8 is a plan schematic diagram illustrating an example of a structure of a semiconductor device according to Variation 2 of Embodiment 1.

FIG. 9 is a graph illustrating a dimensional range of the width of a gate trench and the width of a mesa in the plan view of the semiconductor device according to Embodiment 1.

FIG. 10A is a plan schematic diagram illustrating an example of a structure of a semiconductor device according to Embodiment 2.

FIG. 10B includes a plan schematic diagram and a cross-sectional schematic diagram each illustrating an example of a structure of the semiconductor device according to Embodiment 2.

FIG. 11 is a plan schematic diagram illustrating an example of a structure of the semiconductor device according to Embodiment 2.

FIG. 12A is a plan schematic diagram illustrating an example of a structure of the semiconductor device according to Embodiment 2.

FIG. 12B includes a plan schematic diagram and a cross-sectional schematic diagram each illustrating an example of a structure of the semiconductor device according to Embodiment 2.

FIG. 13 is a plan schematic diagram illustrating an example of a structure of the semiconductor device according to Embodiment 2.

FIG. 14A is a plan schematic diagram illustrating an example of a structure of a semiconductor device according to Embodiment 3.

FIG. 14B includes a plan schematic diagram and a cross-sectional schematic diagram each illustrating an example of a unit cell of the semiconductor device according to Embodiment 3.

FIG. 15A is a graph showing IDS-VGS dependence of a typical semiconductor device.

FIG. 15B is a graph showing IDS-VGS dependence of the semiconductor device according to Embodiment 3.

### DESCRIPTION OF EMBODIMENTS

In the following, specific examples of semiconductor devices according to aspects of the present disclosure will be described with reference to the drawings. The embodiments herein each show one specific example of the present disclosure. Thus, the numerical values, shapes, elements, and the arrangement and connection of the elements described in the following embodiments are examples, and thus are not intended to limit the present disclosure. Furthermore, the drawings are schematic diagrams, and do not necessarily provide strictly accurate illustrations. Throughout the drawings, substantially the same elements are assigned the same reference signs, and the overlapping description is omitted or simplified.

### Embodiment 1

### [1. Structure of Semiconductor Device]

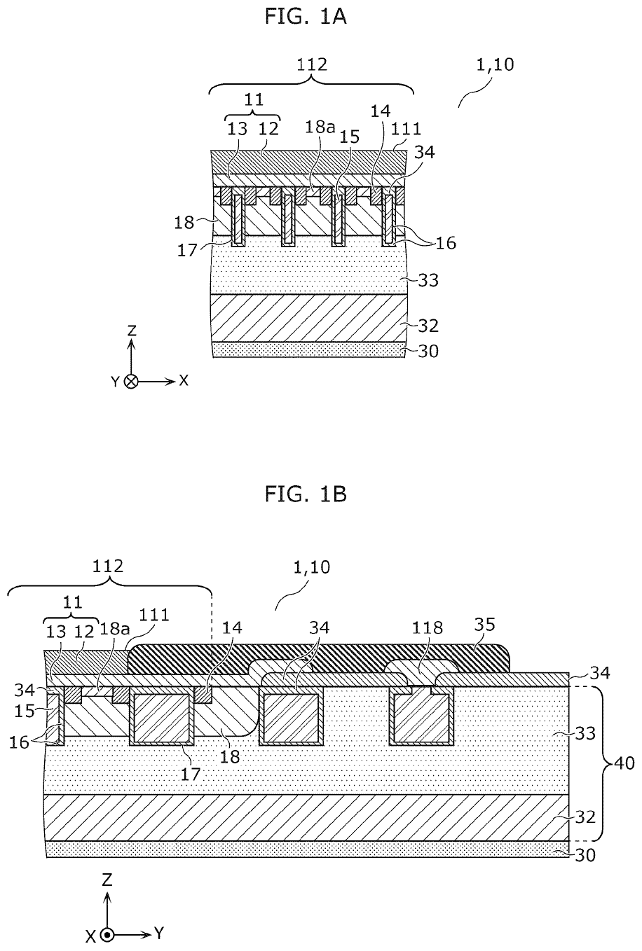

FIG. 1A and FIG. 1B are cross-sectional schematic diagrams illustrating an example of a structure of semiconductor device 1 according to Embodiment 1.

As illustrated in FIG. 1A and FIG. 1B, semiconductor device 1 includes semiconductor substrate 32, metal layer 30, and low-concentration impurity layer 33 provided above semiconductor substrate 32. In the present disclosure, semiconductor substrate 32 and low-concentration impurity layer 33 are collectively referred to as semiconductor layer 40.

Semiconductor substrate 32 is provided on the back surface side of semiconductor layer 40, and is made of first conductivity-type silicon that contains an impurity of a first conductivity type at a first concentration. Low-concentration impurity layer 33 is provided on the front surface side of semiconductor layer 40, is provided in contact with semiconductor substrate 32, contains an impurity of the first conductivity type at a second concentration lower than the first concentration of the impurity of the first conductivity type contained in semiconductor substrate 32, and is of the first conductivity type. Low-concentration impurity layer 33 may be provided on semiconductor substrate 32 by epitaxial growth, for example.

Metal layer 30 is provided in contact with the back surface side of semiconductor layer 40 (semiconductor substrate 32), and has a multilayer structure that includes, for example, layers made of at least one of silver (Ag) or copper (Cu). Metal layer 30 may contain a trace amount of a non-metallic element mixed as an impurity during the manufacturing process of the metal material. Additionally, metal layer 30 does not need to be provided over the entire back surface side of semiconductor layer 40 (semiconductor substrate 32). The thickness of metal layer 30 is at least 3 [μm] and at most 100 [μm], as an example.

As described below, semiconductor device 1 includes vertical MOS transistor 10 (hereinafter also referred to as “transistor 10”) provided in semiconductor layer 40.

In semiconductor layer 40 (low-concentration impurity layer 33), second conductivity-type body regions 18 containing an impurity of a second conductivity type different from the first conductivity type are selectively provided. In an upper portion of each of body regions 18, first conductivity-type source region 14 containing an impurity of the first conductivity type and second conductivity-type body contact region 18a containing an impurity of the second conductivity type at a high concentration are selectively provided.

Gate trench 17 is provided from the upper surface of semiconductor layer 40 and penetrates through source region 14 and body regions 18 to reach a depth up to a portion of low-concentration impurity layer 33. Gate insulating film 16 is provided on the inner surface of gate trench 17, and gate conductor 15 is provided on gate insulating film 16 inside gate trench 17. Gate conductor 15 is an embedded electrode that is embedded inside semiconductor layer 40.

Source electrode 11 is provided above the upper surface of semiconductor layer 40. Source electrode 11 includes portion 12 and portion 13, and portion 12 is connected to source regions 14 and body contact regions 18a via portion 13. Interlayer insulating layer 34 is provided and embedded in upper portions of gate trench 17, and thus gate conductor 15 is not connected to portion 13 of source electrode 11 at the upper surface of semiconductor layer 40 in active region 112 described later.

Portion 12 of source electrode 11 is a layer bonded to solder at the time of reflow when semiconductor device 1 is mounted facedown, and may comprise, as a non-limiting example, a metal material that contains at least one of nickel, titanium, tungsten, or palladium. The surface of portion 12 may be plated with gold, for instance.

Portion 13 of source electrode 11 is a layer that connects portion 12 to semiconductor layer 40, and may comprise, as a non-limiting example, a metal material that contains at least one of aluminum, copper, gold, or silver. The thickness of source electrode 11 including both portion 12 and portion 13 is, for example, at least 2 [μm] and at most 13 [μm].

As illustrated in FIG. 1B, semiconductor layer 40 is covered with interlayer insulating layer 34 having an opening, and portion 13 of source electrode 11, which is connected to source regions 14 and body contact regions 18a through the opening in interlayer insulating layer 34, is provided.

Interlayer insulating layer 34 and portion 13 of source electrode 11 are covered with passivation layer 35 having openings, and portion 12 connected to portion 13 of source electrode 11 through the openings of passivation layer 35 is provided.

As illustrated in FIG. 1A and FIG. 1B, semiconductor substrate 32 functions as a drain region of transistor 10. A portion of low-concentration impurity layer 33 on a side in contact with semiconductor substrate 32 may be a drain region. Note that low-concentration impurity layer 33 is also a drift layer of transistor 10, and may be referred to as drift layer 33 in the present disclosure. Metal layer 30 is a drain electrode of transistor 10. In order to distinguish from an upper-surface drain electrode described later, metal layer 30 may also be referred to as back-surface drain electrode 30.

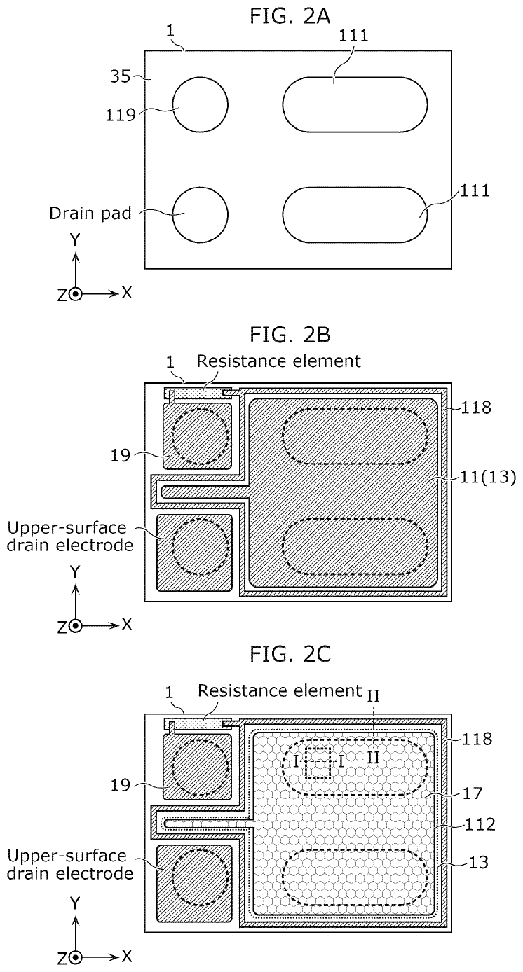

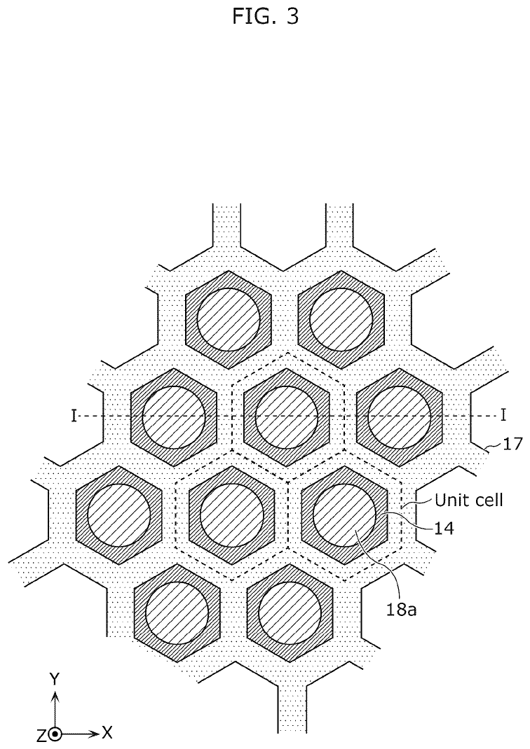

FIG. 2A, FIG. 2B, and FIG. 2C are plan schematic diagrams each illustrating an example of a structure of semiconductor device 1 according to Embodiment 1. FIG. 3 is a plan schematic diagram illustrating an enlarged portion enclosed by a dashed line in FIG. 2C. Note that FIG. 1A and FIG. 1B are cross-sectional views taken along lines I-I and II-II in FIGS. 2C and 3, respectively.

Although FIGS. 2A, 2B, and 2C illustrate a single-structure vertical MOS transistor as an example, semiconductor device 1 according to Embodiment 1 is not limited to a single-structure device and may have a dual or triple structure.

FIG. 2A is a schematic diagram illustrating an appearance of semiconductor device 1. In a plan view, semiconductor device 1 is covered with passivation layer 35 having openings. The openings in passivation layer 35 correspond to source pads 111, gate pad 119, and a drain pad.

FIG. 2B is a schematic diagram illustrating a state excluding passivation layer 35 and interlayer insulating layer 34 from FIG. 2A, where pads that would normally be invisible are indicated with dashed lines to facilitate understanding. As illustrated in FIG. 2B, gate electrode 19 is connected to gate wiring 118, and gate wiring 118 is provided, surrounding source electrode 11. Note that a resistance element may be connected in series between gate electrode 19 and gate wiring 118.

Gate pad 119 is a region in which gate electrode 19 is partially exposed at the surface of semiconductor device 1. Source pads 111 are regions in which source electrode 11 is partially exposed at the surface of semiconductor device 1. The drain pad is a region in which an upper-surface drain electrode (referred to as an upper-surface drain electrode, for the purpose of distinguishing the electrode from metal layer 30 that is a back-surface drain electrode) is partially exposed at the surface of semiconductor device 1.

FIG. 2C and FIG. 3 are schematic diagrams illustrating a state further excluding source electrode 11 from FIG. 2B, with the perimeter of portion 13 of source electrode 11 being indicated by a dotted line to facilitate understanding. To facilitate understanding, the pads that would be invisible are indicated by dashed lines.

As illustrated in FIG. 2C, portion 13 of source electrode 11 covers active region 112 of transistor 10 in the plan view. Active region 112 refers to the minimal range encompassing all portions where channels are formed when a voltage greater than or equal to a threshold is applied to gate conductor 15 of transistor 10. The portions where channels are formed are in the vicinity of gate trench 17, and are portions where the upper portion of gate trench 17 is in contact with source regions 14.

As illustrated in FIG. 2C and FIG. 3, active region 112 of transistor 10 is obtained by repeatedly placing hexagonal unit structures of the same size with no spacing and no overlaps in the plan view. In the plan view, each unit structure is a hexagon having a perimeter defined along center positions of the width of gate trench 17. Stated differently, gate trench 17 of transistor 10 according to Embodiment 1 is provided at positions corresponding to the perimeters of hexagons repeatedly arranged with no spacing in the plan view. Hereafter, this arrangement is referred to as gate trench 17 being provided in a honeycomb arrangement.

Gate trench 17 provided in a honeycomb arrangement has no interruptions within the plane of active region 112. As illustrated in FIG. 2C and FIG. 1B, gate conductor 15 provided inside gate trench 17 is connected to gate electrode 19 via gate wiring 118 surrounding active region 112 in the plan view. Thus, gate conductor 15 has the same electric potential as that of gate electrode 19.

FIG. 2C schematically illustrates only gate trench 17 located inside active region 112 in the plan view. However, as illustrated in FIG. 1B, gate trench 17 may also be provided outside active region 112. Note that gate trench 17 provided outside active region 112 does not contribute to channel formation due to its shape, such as the one not in contact with source region 14 at the upper portions or the one provided outside body region 18. Gate trench 17 provided outside active region 112 is mainly for connecting gate conductor 15 to gate wiring 118.

As illustrated in FIG. 3, unit structures constituting active region 112 of transistor 10 are hexagons each having a perimeter defined along center positions of the width of gate trench 17, in the plan view. In each of the unit structures, a portion of semiconductor layer 40 surrounded by gate trench 17 is referred to as a mesa. In each mesa, source region 14 is provided in contact with the perimeter of gate trench 17 all around in the plan view and is exposed at the upper surface of semiconductor layer 40 (low-concentration impurity layer 33). In the plan view, body contact region 18a is provided on a remaining portion of each mesa, being surrounded by source region 14, and is exposed at the upper surface of semiconductor layer 40 (low-concentration impurity layer 33).

The upper surface of each mesa that includes source region 14 and body contact region 18a is connected to source electrode 11, and the unit structure includes semiconductor substrate 32 and back-surface drain electrode 30. Accordingly, the unit structure is a minimum unit having the function as a transistor, in transistor 10. Hereinafter, this is referred to as a unit transistor cell or a unit cell.

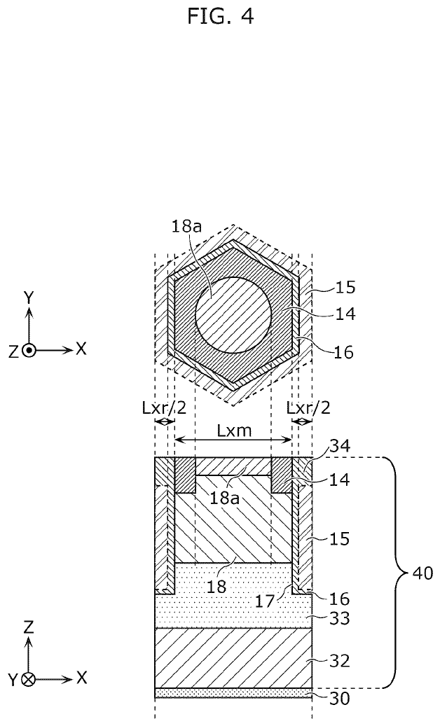

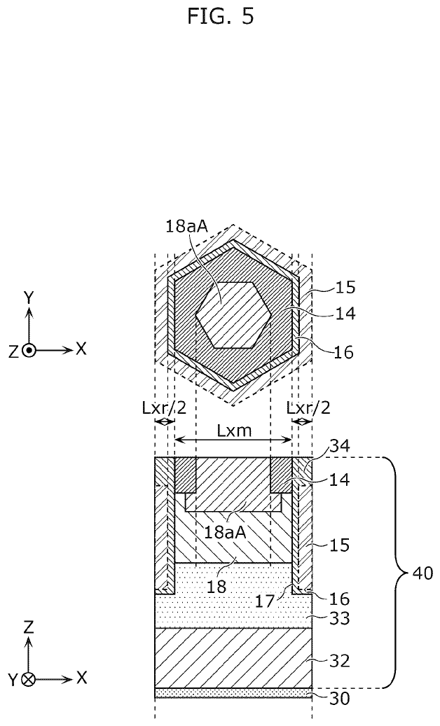

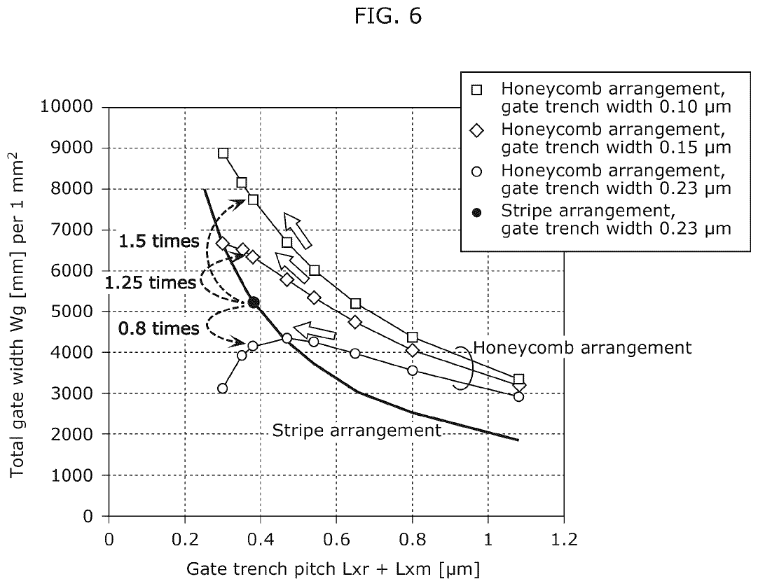

FIG. 4 includes a plan schematic diagram and a cross-sectional schematic diagram of a unit cell of semiconductor device 1 (transistor 10) according to Embodiment 1. FIG. 5 includes a plan schematic diagram and a cross-sectional schematic diagram of a unit cell of semiconductor device 1A (vertical MOS transistor 10A (transistor 10A)) according to Variation 1 of Embodiment 1.

Note that FIG. 4 and FIG. 5 are illustrations excluding source electrode 11, interlayer insulating layer 34 above semiconductor layer 40, and passivation layer 35. Furthermore, interlayer insulating layer 34 inside gate trench 17 is also excluded from the plan schematic diagrams.

Transistor 10A according to Variation 1 of Embodiment 1 is an example in which body contact region 18a is changed to body contact region 18aA according to Variation 1 in a unit cell. Other elements similar to those of transistor 10 according to Embodiment 1 are assigned the same reference signs, and detailed descriptions thereof are omitted as such elements have already been described.

As illustrated in the cross-sectional schematic diagram in FIG. 4 or the cross-sectional schematic diagram in FIG. 5, at least one of body contact region 18a or body contact region 18aA is connected to body region 18 located directly thereunder, and connects portion 13 of source electrode 11 to body region 18. Body contact region 18a contains an impurity of the second conductivity type at a higher concentration than an impurity of the concentration of second conductivity type contained in body region 18.

As illustrated in the cross-sectional schematic diagram in FIG. 4, the lower surface of body contact region 18a may be located at a position shallower than the lower surface of source region 14. As in Variation 1 illustrated in the cross-sectional schematic diagram in FIG. 5, the lower surface of body contact region 18aA may be located at a position deeper than the lower surface of source region 14. Furthermore, a portion of body contact region 18aA may be located directly below source region 14.

In each unit cell, the shape of body contact region 18a exposed at the upper surface of semiconductor layer 40 in the plan view has at least rotational symmetry of 60[°] or less in the clockwise direction, and its center coincides with the center of the hexagon of each unit cell. As one example, the shape may be a substantially circular shape as illustrated in the plan schematic diagram in FIG. 4. The substantially circular shape may not be a perfect circle and, for example, may be a shape resulting from equally chamfering the vertices of a regular hexagon to approach a circle, or may have a perimeter with a certain level of irregularity. Also, the shape of body contact region 18a exposed at the upper surface of semiconductor layer 40 in the plan view may correspond to a hexagon rotated 30[°] clockwise from the hexagon of the unit cell, as in Variation 1 of Embodiment 1 illustrated in the plan schematic diagram in FIG. 5, as an example.

Note that the example of the unit cell of semiconductor device 1 (transistor 10) according to Embodiment 1 illustrated in FIG. 4 and the example of the unit cell of semiconductor device 1A (transistor 10A) according to Variation 1 of Embodiment 1 illustrated in FIG. 5 do not limit the examples to these. For example, the plan schematic diagram in FIG. 4 and the cross-sectional schematic diagram in FIG. 5 may be combined, and as another example, the plan schematic diagram in FIG. 5 and the cross-sectional schematic diagram in FIG. 4 may be combined.

In transistor 10 according to Embodiment 1 and/or in transistor 10A according to Variation 1, in each unit cell, a shape of source region 14 exposed at the upper surface of semiconductor layer 40 in the plan view has a maximum width in a direction away from gate trench 17, on a diagonal line connecting one of the six corners of the unit cell (each mesa) and another corner opposite the one corner across the center of the unit cell (the mesa), as illustrated in the plan schematic diagram in FIG. 4 and the plan schematic diagram in FIG. 5.

As illustrated in FIG. 4, the width of gate trench 17 is smaller than the width of a mesa in semiconductor device 1 (transistor 10) according to Embodiment 1. Note that the width of a mesa is a distance between portions of gate trench 17 parallel to each other in a unit cell in the plan view.

When gate trench 17 is provided in a honeycomb arrangement as illustrated in FIG. 3, gate trench 17 extends in three directions, each 120[°] apart, in the plan view. In Embodiment 1, one of the three directions is defined as the Y direction. The X direction refers to a direction parallel to the upper surface of semiconductor layer 40 and orthogonal to the Y direction. The Z direction refers to a direction orthogonal to both the X direction and the Y direction and is a height direction of semiconductor device 1. In Embodiment 1, as illustrated in FIG. 2C, the X direction and the Y direction are in a relation of being parallel to the perimeter sides of semiconductor device 1 that is rectangular in the plan view.

In semiconductor device 1, for example, with the first conductivity type being N-type and the second conductivity type being P-type, source region 14, semiconductor substrate 32, and low-concentration impurity layer 33 may be N-type semiconductors, and body region 18 and body contact region 18a may be P-type semiconductors.

In semiconductor device 1, for example, with the first conductivity type being P-type and the second conductivity type being N-type, source region 14, semiconductor substrate 32, and low-concentration impurity layer 33 may be P-type semiconductors, and body region 18 and body contact region 18a may be N-type semiconductors.

### [2. Operation of Semiconductor Device]

In the following description, the conduction operation of semiconductor device 1 will be described, assuming that transistor 10 is a so-called N-channel type transistor with the first conductivity type being N-type and the second conductivity type being P-type.

In semiconductor device 1, when a high voltage is applied to back-surface drain electrode 30 and a low voltage is applied to source electrode 11, and a voltage higher than or equal to a threshold is applied to gate electrode 19 with source electrode 11 serving as the reference, channels are formed in the vicinity of gate insulating film 16 in body region 18. As a result, current flows through the path through metal layer 30—semiconductor substrate 32—low-concentration impurity layer 33—a channel formed in body region 18—source region 14—source electrode 11, and semiconductor device 1 enters a conductive state. At the contact surface between body region 18 and low-concentration impurity layer 33 in this conduction path, there is a PN junction, which functions as a body diode.

When a high voltage is applied to source electrode 11 and a low voltage is applied to back-surface drain electrode 30, current flows through the body diode along the path through source electrode 11—body contact region 18a—body region 18—low-concentration impurity layer 33—semiconductor substrate 32—metal layer 30.

### [3. Consideration]

Hereinafter, the effects achieved by semiconductor device 1 according to Embodiment 1 will be described based on the examinations conducted by the present inventors. The present inventors conducted examinations assuming width Lxr [μm] of a gate trench and distance (mesa width) Lxm [μm] between portions of the gate trench both in the range of approximately 0.5 [μm] or less (the width of the gate trench and the distance between portions of the gate trench being collectively approximately 1.0 [μm] or less).

FIG. 6 illustrates relations between arrangements and structural dimensions of the gate trench in the plan view and twice the total length of the gate trench within active region 112, that is, the total gate width within active region 112. The horizontal axis represents the gate trench pitch, that is, the sum of the width of one portion of the gate trench and the width of one mesa (Lxr+Lxm [μm]), and the vertical axis represents the total gate width (Wg [mm]) per 1 [mm²] of the active region. Hereinafter, the total gate width per 1 [mm²] of the active region is simply referred to as a total gate width.

The outlined white markers show the results when the gate trench is provided in a honeycomb arrangement as illustrated in FIG. 3. Furthermore, square markers show the results when the width of the gate trench is 0.10 [μm], rhombus markers show the results when the width of the gate trench is 0.15 [μm], and white circle markers show the results when the width of the gate trench is 0.23 [μm].

In contrast, the thick line shows the results when in the plan view, straight gate trenches are provided at equal intervals horizontally (hereinafter referred to as being provided in a stripe arrangement), with the width of the gate trenches being 0.23 [μm]. On the thick line, the black circle marker shows the result when the gate trench pitch is 0.38 [μm] (therefore, the width of a mesa is 0.15 [μm]).

When gate trenches are provided in a stripe arrangement, the number of gate trenches provided per unit area increases with a decrease in the gate trench pitch, so the total gate width increases. Conversely, the number of gate trenches provided per unit area decreases with an increase in the gate trench pitch, so the total gate width decreases. Thus, in FIG. 6, the thick line shows a monotonically decreasing tendency.

However, when the gate trench is provided in a honeycomb arrangement, a different tendency appears. At the level where the width of the gate trench is 0.23 [μm] as shown by the white circle markers, when the gate trench pitch decreases to 0.46 [μm] or less (that is, when the mesa width decreases to 0.23 [μm] or less), a tendency for the total gate width to decrease appears. On the graph in FIG. 6, a comparison between the honeycomb arrangement (shown by the white circle markers) and the stripe arrangement (shown by the black circle marker) with the same gate trench width of 0.23 [μm] shows that the total gate width of the honeycomb arrangement is only approximately 0.8 times the total gate width of the stripe arrangement, even at the same gate trench pitch of 0.38 [μm] (that is, the mesa width of 0.15 [μm]).

This is due to the fact that in the case of the honeycomb arrangement, the total gate width is the sum total of the lengths of the perimeters of individual mesas in the plan view. When viewing a unit cell in the plan view, if the width of a gate trench is larger than the width of a mesa (Lxr>Lxm), the inside of the gate trench (gate insulating film 16 and gate conductor 15) occupies most of the unit cell, so the mesa is small to begin with. Under such conditions, even if the gate trench pitch is reduced, the length of the perimeter of a mesa in the plan view does not increase, but rather decreases.

Conversely, when the width of a gate trench is less than or equal to the width of a mesa in the plan view (Lxr≤Lxm), even in the honeycomb arrangement, the length of the perimeter of the mesa can be increased by decreasing the gate trench pitch. Under such a condition, the honeycomb arrangement can make the total gate width longer than that in the stripe arrangement.

On the graph in FIG. 6, a comparison between the honeycomb arrangement (rhombus markers, square markers) and the stripe arrangement (a black circle marker) at the same gate trench pitch of 0.38 [μm] shows that the total gate width increases by approximately 1.25 times with the gate trench width of 0.15 [μm] (rhombus markers, the mesa width of 0.23 [μm]), and the total gate width increases by approximately 1.5 times with the gate trench width of 0.10 [μm] (square markers, the mesa width of 0.28 [μm]).

This is due to the fact that the gate trench can be provided two-dimensionally in the honeycomb arrangement, as compared to the stripe arrangement. Thus, in order to obtain the advantage of increasing the total gate width in the honeycomb arrangement, it is an essential condition to make the width of a gate trench less than or equal to the width of a mesa (Lxr≤Lxm).

In FIG. 6, looking at the plot where the width of the gate trench is 0.15 [μm] in the honeycomb arrangement (shown by rhombus markers), it appears that the total gate width reaches its maximum when the gate trench pitch is 0.30 [μm], that is, when the mesa width is also 0.15 [μm] and thus the gate trench width and the mesa width are the same (the leftmost plot). Although there is no plot in the range of the graph in FIG. 6, in the plot where the gate trench width is 0.10 [μm] in the honeycomb arrangement (shown by square markers), the total gate width reaches its maximum when the gate trench pitch is 0.20 [μm], that is, when the mesa width is also 0.10 [μm] and thus the gate trench width and the mesa width are the same.

Next, it will be described that Lxm/3≤Lxr may be satisfied between gate trench width Lxr and mesa width Lxm.

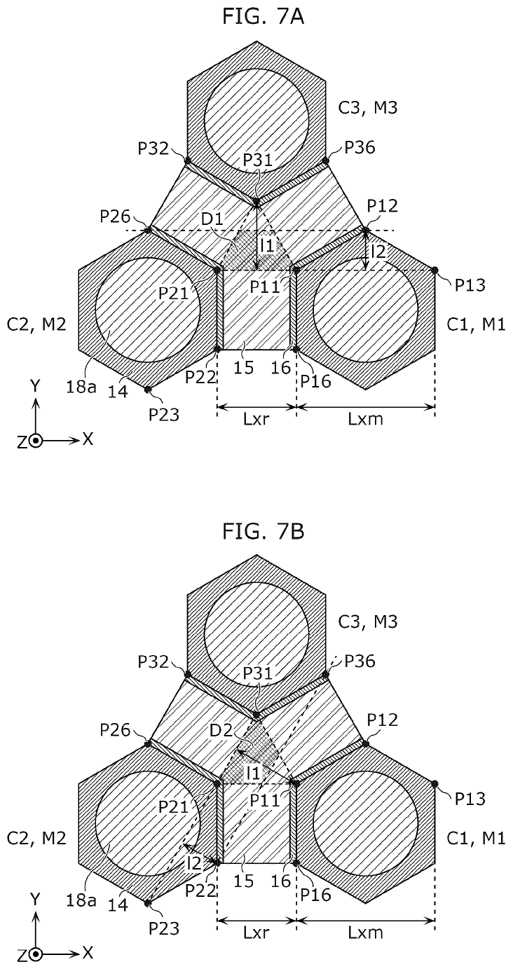

When providing gate trench 17 in a honeycomb arrangement, a triangular region surrounded by three adjacent mesas within gate trench 17 in the plan view (enclosed by the dashed lines in FIG. 7A and FIG. 7B described later) is not in contact with any adjacent mesas via gate insulating film 16. Thus, the region is less likely to contribute to the formation of channels when a voltage higher than or equal to the threshold is applied to gate conductor 15.

FIGS. 7A and 7B are plan schematic diagrams illustrating an enlarged portion of extracted three unit cells adjacent in the plan view within active region 112 of transistor 10 according to Embodiment 1.

The three unit cells adjacent in the plan view are first unit cell C1, second unit cell C2 that is at the same position in the Y direction as first unit cell C1 and at a position opposite first unit cell C1 across gate trench 17 in the X direction, and third unit cell C3 that is between first unit cell C1 and second unit cell C2 in the X direction and at a different position in the Y direction from first unit cell C1 and second unit cell C2.

In the plan view, the triangular region has, on its perimeter, three vertices that are corner P11 of first mesa M1 included in first unit cell C1, corner P21 of second mesa M2 included in second unit cell C2, and corner P31 of third mesa M3 included in third unit cell C3.

The corners of first mesa M1 that is a hexagon in the plan view are corner P11 that forms one of the vertices of the triangular region, and clockwise therefrom, corner P12, corner P13, corner P14, corner P15, and corner P16. For second mesa M2 and third mesa M3 that are hexagons in the plan view, the corners are given reference signs in the same manner. FIGS. 7A and 7B illustrate only some of the reference signs for the corners.

In FIG. 7A, when the triangular region in the plan view is seen focusing on the direction in which first unit cell C1 and second unit cell C2 are opposite in the plan view (the X direction in FIG. 7A), a voltage applied to region D1 shaded in FIG. 7A is considered to contribute to the channel formation along the side from corner P11 to corner P12 of first mesa M1 in the plan view and to the channel formation along the side from corner P21 to corner P26 of second mesa M2 in the plan view.

Thus, length 11 of a perpendicular dropped from corner P31 of the triangular region toward a base connecting corner P11 and corner P21 in the plan view may be longer than length 12 of a perpendicular dropped from corner P12 of first mesa M1 toward a straight line connecting corner P11 and corner P13 in the X direction in the plan view. When this relation is satisfied, at least a portion of the triangular region (shaded region D1 illustrated in FIG. 7A) can be utilized to form a channel along the entire length of a side from corner P11 to corner P12 of first mesa M1 in the plan view and form a channel along the entire length of a side from corner P21 to corner P26 of second mesa M2 in the plan view.

In the plan view,

$$I 1 = \frac{\sqrt{3}}{2} \times Lxr \qquad [ Math . 1 ]$$

$$and$$

$$I 2 = \frac{\sqrt{3}}{6} \times L x m . \qquad [ Math . 2 ]$$

Thus, when the above relation (11≥12) is simplified, Lxr≥Lxm/3 may be satisfied.

FIG. 7B illustrates a state when the triangular region in the plan view is seen, focusing on a direction in which second unit cell C2 and third unit cell C3 are opposite each other (in FIG. 7B, the direction resulting from rotating the Y direction clockwise by 30[°]). The voltage applied to region D2 shaded in FIG. 7B is considered to contribute to the channel formation along the side from corner P21 to corner P22 of second mesa M2 in the plan view and to the channel formation along the side from corner P31 to corner P36 of third mesa M3 in the plan view.

Due to geometric symmetry, when Lxr≥Lxm/3 is also satisfied in FIG. 7B, at least a portion of the triangular region (shaded region D2 illustrated in FIG. 7B) can be utilized to form a channel along the entire length of a side from corner P21 to corner P22 of second mesa M2 in the plan view and form a channel along the entire length of a side from corner P31 to corner P36 of third mesa M3 in the plan view.

Although not illustrated, the same conclusion is reached when the triangular region in the plan view is seen, focusing on a direction in which third unit cell C3 and first unit cell C1 are opposite each other.

Thus, when gate trench 17 is provided in a honeycomb arrangement, in order to effectively utilize a triangular region surrounded by three adjacent mesas in the plan view within gate trench 17 for channel formation in the three mesas, Lxr≥Lxm/3 may be satisfied. When Lxr≥Lxm/3 is satisfied, entire gate conductor 15 embedded inside gate trench 17 can be effectively utilized.

Next, a relation that may be satisfied between the shapes of source region 14 and body contact region 18a in the plan view, which are exposed at the upper surface of each mesa, will be described.

When gate trench 17 is provided in a honeycomb arrangement and a voltage higher than or equal to the threshold is applied to gate conductor 15 embedded in gate trench 17, a width of a channel formed in each mesa in the plan view becomes largest in the vicinity of corners of the mesa due to geometric features.

A channel width refers to the length of a channel in a direction away from gate trench 17 in the plan view. Generally, a channel width increases with an increase in a voltage applied to gate conductor 15, but when gate trench 17 is provided in a honeycomb arrangement, even if a voltage applied to gate conductor 15 is constant, a difference in channel width appears due to differences in position within a mesa.

This is because, for example, in FIG. 7A, in the vicinity of corner P11 of first mesa M1, a voltage applied from a portion of gate trench 17 along a side from corner P11 to corner P16 overlaps a voltage applied from a portion of gate trench 17 along a side from corner P11 to corner P12 and furthermore, there is also contribution from the triangular region.

Thus, a state in the vicinity of corners of each mesa (not limited to corner P11) substantially becomes a state equivalent to the one when a gate voltage higher than those applied to other portions is applied, and a channel width increases so that conductivity resistance decreases. Thus, in the case of the honeycomb arrangement, current tends to concentrate at corners of each mesa.

However, in a structure where both the width of gate trench 17 and the width of mesas are reduced to a finer scale of 0.5 [μm] or less, corners of the mesas are scattered at high density within a plane of active region 112, so adverse effects such as local heat generation are unlikely to occur. Thus, in such a fine structure, by utilizing an increase in channel width and current concentration at corners of mesas, conductivity resistance of channels can be effectively reduced.

In a plan view, a line connecting one corner of each mesa to another corner opposite the one corner across the center of the mesa on a straight line is referred to as a diagonal line. For example, the diagonal lines of first mesa M1 in FIG. 7A are a line connecting corner P11 to corner P14, a line connecting corner P12 to corner P15, and a line connecting corner P13 to corner P16.

As described above, when utilizing an increase in channel width at each corner of each mesa, in the plan view, source region 14 may be provided such that a length in a direction away from gate trench 17 is relatively larger on a diagonal line from the corner.

Thus, in the plan view, a shape of source region 14 exposed at the upper surface of semiconductor layer 40 (low-concentration impurity layer 33) provided in each of the unit cells may have a maximum width in a direction away from gate trench 17, on a diagonal line connecting one corner of the unit cell and another corner opposite the one corner on a straight line across the center of the unit cell.

In each of the unit cells, in the plan view, source region 14 and body contact region 18a exposed at the upper surface of semiconductor layer 40 in the mesa may be provided to exhibit such features as above. As an example, as illustrated in the plan schematic diagrams in FIG. 3 and FIG. 4, in the plan view, the shape of body contact region 18a provided in each of the unit cells and exposed at the upper surface of semiconductor layer 40 may be substantially circular and concentric with the unit cell.

As another example, as illustrated in the plan schematic diagram of FIG. 5, in the plan view, the shape of body contact region 18a exposed at the upper surface of semiconductor layer 40 is a hexagon concentric with the unit cell, and the hexagon may be in a location rotated 30[°] clockwise from the hexagon of the unit cell.

In the plan view, in each of the unit cells, providing source region 14 and body contact region 18a to have such exposed shapes as described above in a mesa makes it possible to sufficiently utilize a channel that particularly widens at corners of the mesa, and the effect of reducing the conductivity resistance of the channel can be obtained.

A feature of the shapes of body contact regions 18a and 18aA in the plan views as illustrated in the plan schematic diagrams in FIG. 4 and FIG. 5 is, first, to have rotational symmetry of 60[°] or less in a clockwise direction by itself. Furthermore, another feature is that in the plan view, the center of body contact region 18a/18aA and the center of the hexagonal shape of the unit cell coincides with each other. With such two features, the same effect can be achieved at each of the six corners of the unit cell (or the mesa) in the plan view.

Thus, semiconductor device 1 according to Embodiment 1 includes: vertical metal-oxide semiconductor (MOS) transistor 10 that includes: semiconductor substrate 32 of a first conductivity type, semiconductor substrate 32 containing an impurity at a first concentration; low-concentration impurity layer 33 of the first conductivity type, low-concentration impurity layer 33 being provided above and in contact with semiconductor substrate 32 and containing an impurity at a second concentration lower than the first concentration of the impurity contained in semiconductor substrate 32; body region 18 of a second conductivity type different from the first conductivity type, body region 18 being provided in low-concentration impurity layer 33; source region 14 of the first conductivity type, source region 14 being provided in body region 18; body contact region 18a of the second conductivity type, body contact region 18a being provided in body region 18; source electrode 11 connected to body contact region 18a and source region 14; gate trench 17 provided from an upper surface of low-concentration impurity layer 33 and penetrating through body region 18 to reach a depth up to a portion of low-concentration impurity layer 33; gate insulating film 16 provided inside gate trench 17; and gate conductor 15 provided above gate insulating film 16 and embedded inside gate trench 17. In a plan view of low-concentration impurity layer 33, active region 112 of vertical MOS transistor 10 includes unit cells repeatedly arranged within a plane of active region 112, in the plan view, each of the unit cells is a hexagon having a perimeter defined along center positions of a width of gate trench 17, in the plan view, in each of the unit cells, source region 14 in contact with gate trench 17 along an entire perimeter and body contact region 18a surrounded by source region 14 are exposed at the upper surface of low-concentration impurity layer 33, in the plan view, in each of the unit cells, a shape of body contact region 18a exposed at the upper surface of low-concentration impurity layer 33 has a center that coincides with a center of the unit cell and rotational symmetry of 60[°] or less in a clockwise direction, in the plan view, in each of the unit cells, a shape of source region 14 exposed at the upper surface of low-concentration impurity layer 33 has a maximum width in a direction away from gate trench 17, on a diagonal line connecting one corner of the unit cell and another corner opposite the one corner on a straight line across the center of the unit cell, and in the plan view, Lxm/3≤Lxr≤Lxm is satisfied, where Lxr [μm] denotes the width of gate trench 17, and Lxm [μm] denotes a distance between parallel portions of gate trench 17 that face each other.

However, in a fine-scale unit cell, if the width of source region 14 becomes excessively large in the plan view, it becomes difficult to sufficiently secure the area of body contact region 18a, and there is a risk that the function of transistor 10 may be impaired. Thus, in the plan view, the width of body contact region 18a on a diagonal line provided in a unit cell may be wider than the width of source region 14 on the diagonal line provided in the unit cell.

Note that here, the width of source region 14 on the diagonal line provided in each of the unit cells in the plan view refers to the sum of the widths of portions of source region 14 in contact with portions of gate trench 17 on both sides with body contact region 18a being located therebetween, when viewed along a certain diagonal line.

Now, returning to FIG. 6, when the gate trench is provided in a honeycomb arrangement, in the case where the gate trench width is 0.15 [μm] or less (plots indicated by rhombus markers and square markers), it can be seen that an increase in the total gate width per unit area due to a decrease in the gate trench pitch is sharp. This shows that, in the case where the width of the gate trench provided in a honeycomb arrangement is 0.15 [μm] or less, if the active region can be expanded even slightly, the effect of increasing the total gate width thereby is large in the semiconductor device.

Providing the gate trench in a honeycomb arrangement has the effect of making it easier to expand the active region as compared to the case of providing gate trenches in a stripe arrangement, which will be described below.

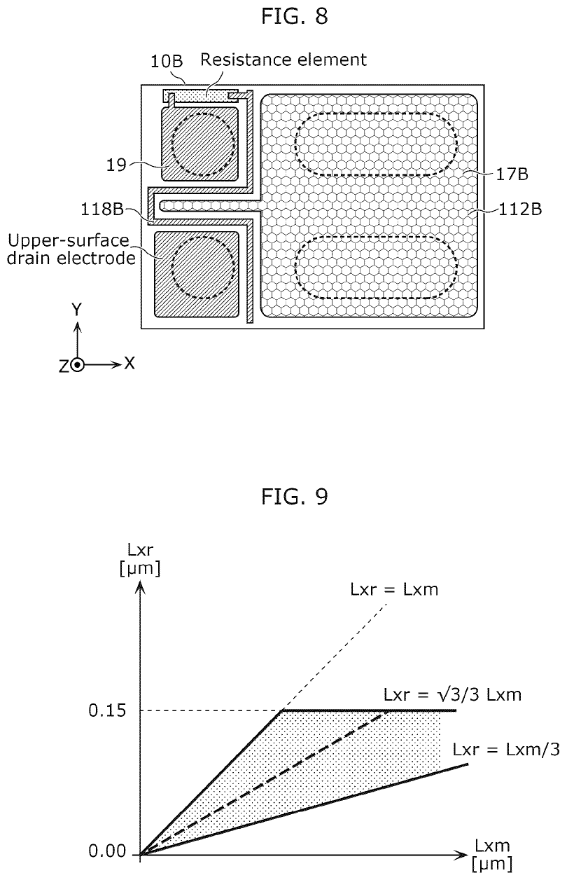

FIG. 8 illustrates a plan schematic diagram of semiconductor device 1B (vertical MOS transistor 10B (transistor 10B)) according to Variation 2 of Embodiment 1. Note that transistor 10B according to Variation 2 of Embodiment 1 shows an example in which gate trench 17 is changed to gate trench 17B according to Variation 2, active region 112 is changed to active region 112B according to Variation 2, and gate wiring 118 is changed to gate wiring 118B according to Variation 2. Other elements similar to those of transistor 10 according to Embodiment 1 are assigned the same reference signs, and detailed descriptions thereof are omitted as the elements have already been described.

The position where gate wiring 118B of transistor 10B according to Variation 2 illustrated in FIG. 8 is provided is different from that of gate wiring 118 of transistor 10 according to Embodiment 1 illustrated in FIG. 2C. In transistor 10 according to Embodiment 1, as illustrated in FIG. 2C, gate wiring 118 is provided on all the sides surrounding active region 112 in the plan view. In contrast, in Variation 2 illustrated in FIG. 8, gate wiring 118B is provided only between gate electrode 19 and active region 112B, between the upper-surface drain electrode and active region 112B, and between gate electrode 19 and the upper-surface drain electrode, among the sides surrounding active region 112B in the plan view.

Accordingly, in transistor 10B according to Variation 2, as compared to transistor 10 according to Embodiment 1, the region where gate trench 17B is provided, active region 112B, and furthermore, the region where the source electrode is connected to the upper surface of semiconductor layer 40, although not illustrated, are each increased in area in the plan view.

Note that, to make it easy to compare with the example illustrated in FIG. 2C, FIG. 8 illustrates a state excluding passivation layer 35, interlayer insulating layer 34, and source electrode 11, similarly to FIG. 2C. To facilitate understanding, in FIG. 8, the pads that would be invisible are indicated by dashed lines.

In transistor 10B according to Variation 2 illustrated in FIG. 8, in the plan view, gate conductor 15 is connected at the portions of gate wiring 118B provided only between gate electrode 19 and active region 112B, between the upper-surface drain electrode and active region 112B, and between gate electrode 19 and the upper-surface drain electrode. Among the sides surrounding active region 112B in the plan view, gate wiring 118B is not provided along the other sides, and thus there are portions where gate conductor 15 terminates without being connected to gate wiring 118B on the periphery of active region 112B.

Gate trench 17B (gate conductor 15) provided in a honeycomb arrangement is not interrupted within the plane of active region 112B. Thus, even if gate wiring 118B is provided only at limited positions as stated above and gate wiring 118B and gate conductor 15 are connected at only these positions, there is no hindrance to causing gate conductor 15 within the plane of active region 112B to uniformly have the same electric potential.

In transistor 10B according to Variation 2 illustrated in FIG. 8, gate wiring 118B is provided only at limited locations among the sides surrounding active region 112B in the plan view, and thus it is possible to expand, by that amount, the region where gate trench 17B is provided in portions along the other sides, as compared to the example illustrated in FIG. 2C. Thus, in transistor 10B according to Variation 2, active region 112B can be expanded and the total gate width increases, as compared to transistor 10 according to Embodiment 1 illustrated in FIG. 2C.

As described above, providing the gate trench (gate conductor) in a honeycomb arrangement has an effect of making it easier to expand the active region, as compared to the case of providing gate trenches in a stripe arrangement. Furthermore, as illustrated in FIG. 6, if the width of the gate trench is reduced to 0.15 [μm] or less, as with transistor 10B according to Variation 2 illustrated in FIG. 8, the total gate width can be significantly increased if the active region can be expanded even slightly.

Thus, Lxr≤0.15 [μm] may be satisfied, and in the plan view, gate conductor 15 may include a portion that terminates without being connected to gate wiring 118B at a periphery of active region 112B. With the above configuration, since the region where gate wiring 118B is provided can be reduced and that portion can be utilized as active region 112B, the total gate width can be effectively increased.

In the case where gate trench 17 is provided in a honeycomb arrangement, FIG. 9 illustrates a range of the dimensional relation between width Lxr [μm] of the gate trench and width Lxm [μm] of mesas. When Lxr≤Lxm, total gate width Wg can be increased as compared to the case where gate trenches are provided in a stripe arrangement. When Lxm/3≤Lxr, gate conductor 15 embedded inside gate trench 17 can be effectively utilized along the entire length. When Lxr≤0.15 [μm], it becomes easier to obtain the effect of increasing the total gate width by expanding active region 112 even slightly. All of them can achieve effects of reducing the conductivity resistance of channels of transistor 10. The range shown with shading in FIG. 9 is a range that satisfies all the conditions.

The dashed line in FIG. 9 shows a condition under the relation:

$$Lxr = \frac{\sqrt{3}}{3} \times L x m . \qquad [ Math . 3 ]$$

In transistor 10 under this condition, the length of one side of each mesa and the width of gate trench 17 have the same dimension, in the plan view. Thus, in the plan view, in active region 112, the spacing between nearest adjacent corners among the corners of each mesa is equal within the entire plane of active region 112, and the effect of making it difficult for current concentration or heat concentration to occur can be obtained.

### Embodiment 2

In the following, a description will be given of semiconductor device 1C (vertical MOS transistor 10C (transistor 10C)) according to Embodiment 2, in which some elements are changed from semiconductor device 1 (transistor 10) according to Embodiment 1.

Transistor 10C according to Embodiment 2 is an example in which gate trench 17 is changed to gate trench 17C according to Embodiment 2. Here, regarding transistor 10C according to Embodiment 2, the elements similar to those of transistor 10 according to Embodiment 1 are assigned the same reference signs and detailed descriptions thereof are omitted as such elements have already been described, so the description centers on the differences from transistor 10.

### [1. Structure of Semiconductor Device]

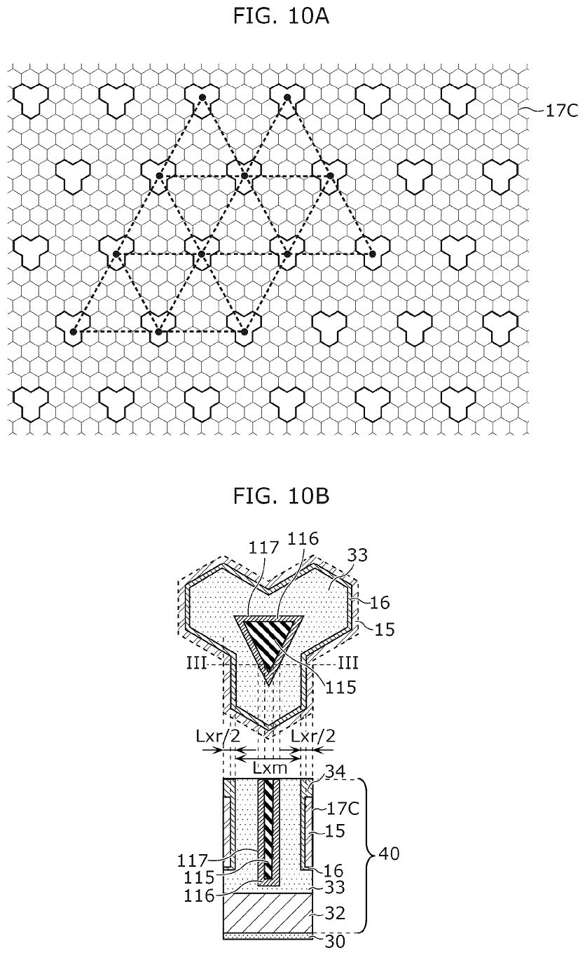

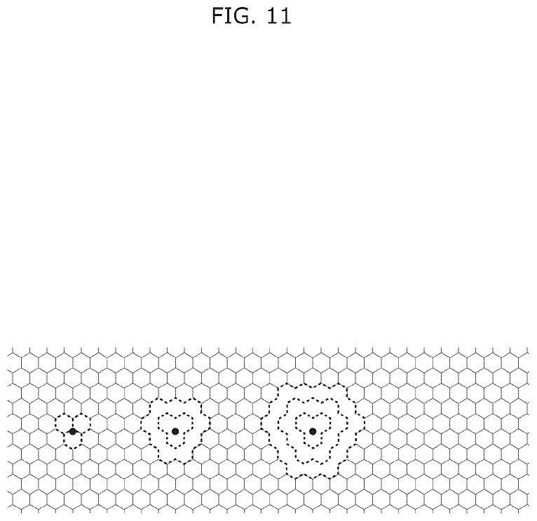

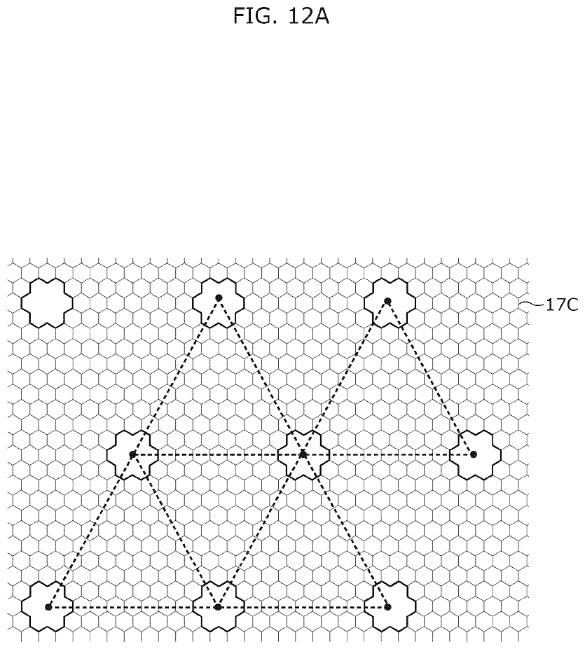

FIG. 10A is a plan schematic diagram illustrating a portion of a structure in active region 112 of semiconductor device 1C (transistor 10C) according to Embodiment 2. In semiconductor device 1C according to Embodiment 2 as well, gate trench 17C is provided in a honeycomb arrangement in the plan view. However, as illustrated in FIG. 10A, gate trench 17C of transistor 10C according to Embodiment 2 differs from gate trench 17 of transistor 10 according to Embodiment 1 in that regions where gate trench 17C is not provided are periodically provided two-dimensionally within the plane of active region 112.

Each of the regions where gate trench 17C is not provided has a shape resulting from combining a plurality of adjacent unit cells in the plan view, and neither source region 14 nor body contact region 18a is provided inside the region.

In each of the regions where gate trench 17C is not provided, shield trench 117 that reaches from the upper surface of semiconductor layer 40 to a position deeper than gate trench 17C is provided. Shield insulating film 116 is provided on the internal surface of shield trench 117. Shield insulating film 116 may be made of the same material as gate insulating film 16, which is, for example, silicon oxide, and may be provided simultaneously with gate insulating film 16.

Inside shield trench 117, shield conductor 115 connected to source electrode 11 is provided above shield insulating film 116. Shield conductor 115 may be made of the same material as that of gate conductor 15 or source electrode 11.

Hereinafter, as illustrated in FIG. 10A, the regions where gate trench 17C is not provided and that are periodically arranged within the plane of active region 112 in the plan view will be individually referred to as shield regions.

FIG. 10B includes a plan schematic diagram and a cross-sectional schematic diagram each illustrating an enlarged view of one shield region. To facilitate understanding, FIGS. 10A and 10B illustrate a structure excluding passivation layer 35, interlayer insulating layer 34 above semiconductor layer 40, and source electrode 11. Furthermore, interlayer insulating layer 34 inside gate trench 17C is also excluded from the plan schematic diagram. Note that the cross-sectional schematic diagram in FIG. 10B shows a cross-section when viewed along III-III in the plan schematic diagram in FIG. 10B.

As illustrated in FIG. 10A, in the plan view, the shield regions are arranged with the centers thereof being located at the vertices of equilateral triangles. The length of the sides of the equilateral triangle is selected according to a breakdown voltage of semiconductor device 1.

The operation of transistor 10C according to Embodiment 2 is the same as that of transistor 10 according to Embodiment 1, so the description thereof is omitted.

### [2. Consideration]

Hereinafter, a description will be given of the effects achieved semiconductor to by device 1C (transistor 10C) according Embodiment 2.

Without distinguishing between transistor 10 according to Embodiment 1 and transistor 10C according to Embodiment 2, the electric potential difference between back-surface drain electrode 30 (metal layer 30) and source electrode 11 is referred to as a drain-source voltage or simply a drain voltage (VDS [V]). A maximum specification voltage (BVDS [V]) that is a voltage guaranteed for safe use of transistor 10 or transistor 10C even if that voltage is applied across the drain and the source, which is normally stated in the product specification, may be referred to as a drain breakdown voltage or simply a breakdown voltage in the present disclosure.

In transistor 10 or transistor 10C, a PN junction is provided at the boundary between body region 18 and low-concentration impurity layer 33, and a depletion layer is generated across the PN junction. In order to increase the drain breakdown voltage, a structure is to be adopted in which when transistor 10 or transistor 10C is off, the depletion layer can sufficiently expand.

As an example, in order that the depletion layer sufficiently expands, it is effective to decrease the carrier density of low-concentration impurity layer 33 (increase the resistivity thereof) or to increase the thickness of low-concentration impurity layer 33. However, such measures may not be adopted since the conduction resistance of a current path from a tip of gate trench 17 to back-surface drain electrode 30 (metal layer 30) is increased in the case of transistor 10 according to Embodiment 1.

In contrast, transistor 10C according to Embodiment 2 includes shield trenches 117 that are deeper than gate trench 17C. Furthermore, shield conductors 115 have the same electric potential as that of source electrode 11, and thus while the transistor is off, shield trenches 117 can push down the expansion of the depletion layer and reduce the intensity of an electric field that occurs near the tips of gate trench 17C. Thus, the breakdown voltage of transistor 10C is increased as compared to transistor 10 according to Embodiment 1 in which shield trenches 117 are not provided, without controlling the physical property values of low-concentration impurity layer 33.

Shield trenches 117 are provided deeper than gate trench 17C, and thus providing shield trenches 117 requires a wide area in the plan view. Transistor 10 according to Embodiment 1 has a fine structure in which gate trench 17 is provided in a honeycomb arrangement, and furthermore, both the width of gate trench 17 and the width of mesas are 0.50 [μm] or less. Thus, the area of each unit cell is small, and it is difficult to provide a shield trench inside one unit cell.

In contrast, in transistor 10C according to Embodiment 2, since a shield region resulting from combining a plurality of adjacent unit cells in the plan view is provided, the area for providing shield trenches 117 can be secured. However, by that amount, the total length of gate trench 17C in the plan view, that is, the total gate width decreases to some extent, so the conductivity resistance of a channel increases as compared to that of transistor 10 according to Embodiment 1. Thus, the area of each individual shield region may be minimal within the range that can secure a sufficient area for providing designed shield trench 117.

There are several methods for combining a plurality of unit cells to form a shield region. FIG. 10A illustrates an example in which the smallest region is configured of three unit cells among such methods. The center of a shield region is a corner where the vertices of the three unit cells overlap. In FIG. 10A, in some shield regions, the centers are indicated by black dots. When the area of a shield region configured by combining three unit cells is insufficient for providing shield trench 117 having a designed structure, another ring of surrounding unit cells may be combined. FIG. 11 illustrates examples showing how to combine unit cells.

In FIG. 11, the leftmost example of a shield region is the same as those illustrated in FIGS. 10A and 10B, and results from combining three unit cells. The central example of a shield region is configured of a total of 12 unit cells obtained by uniformly adding one ring of unit cells along the perimeter of the shield region shown on the left. The rightmost example of a shield region is configured of a total of 27 unit cells obtained by further uniformly adding one ring of unit cells along the perimeter of the shield region shown in the center. In all cases, the center of the shield region remains unchanged and consistent.

The shield regions illustrated in FIG. 11 are examples showing how to form regions such that their areas become 3n² times that of a unit cell (n is an integer of 1 or more). The shape of a shield region may be selected according to the designed shape of shield trench 117 and the manufacturing method, but n may be as small as possible.

Note that in the plan view, shield trenches 117 may be each provided to include the center of an individual shield region. The plan schematic diagram in FIG. 10B illustrates an example in which, in the plan view, shield trench 117 is a triangle and is provided such that the center of the shield region is included in this triangle.

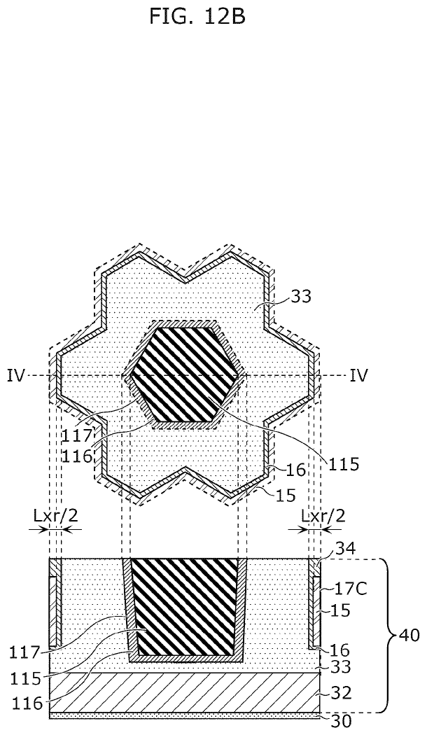

FIG. 12A illustrates another way of combining a plurality of unit cells for the purpose of forming a shield region. FIG. 12A is a plan schematic diagram illustrating an example in which how shield regions are arranged is changed and illustrating a portion of a structure in active region 112, in transistor 10C according to Embodiment 2. FIG. 12A illustrates an example in which each shield region is configured of seven unit cells. FIG. 12B includes a plan schematic diagram and a cross-sectional schematic diagram each illustrating one enlarged shield region. To facilitate understanding, FIGS. 12A and 12B illustrate a structure excluding passivation layer 35, interlayer insulating layer 34 above semiconductor layer 40, and source electrode 11. Furthermore, interlayer insulating layer 34 inside gate trench 17C is also excluded from the plan schematic diagram. Note that the cross-sectional schematic diagram in FIG. 12B shows a cross section when viewed along IV-IV in the plan schematic diagram in FIG. 12B.

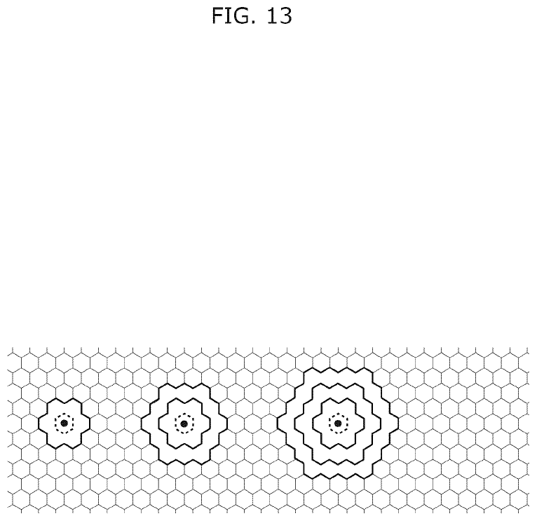

In the example illustrated in the plan schematic diagrams in FIG. 12A and FIG. 12B, the center of a shield region is the center of a unit cell located in the center. In FIG. 12A, the centers are shown with black dots only in some of the shield regions. When the area of a shield region configured by combining seven unit cells is insufficient for providing shield trench 117 having the designed structure, another ring of surrounding unit cells may be combined. FIG. 13 illustrates examples showing how to combine unit cells.

In FIG. 13, the leftmost example of a shield region is the same as that illustrated in FIGS. 12A and 12B, and results from combining seven unit cells. The central example of a shield region is configured of a total of 19 unit cells obtained by uniformly adding one ring of unit cells along the perimeter of the shield region shown on the left. The rightmost example of a shield region is configured of a total of 37 unit cells obtained by further uniformly adding one ring of unit cells along the perimeter of the shield region shown in the center. In all cases, the center of the shield region remains unchanged and consistent.

The shield regions illustrated in FIG. 13 are examples showing how to form the regions such that their areas are 1+3n(n+1) times that of a unit cell (n is an integer of 1 or more). The shape of a shield region may be selected according to the designed shape of shield trench 117 and the manufacturing method, but n may be as small as possible.

Note that in the plan view, shield trenches 117 may be each provided to include the center of an individual shield region. The plan schematic diagram in FIG. 12B illustrates an example in which in the plan view, shield trench 117 corresponds to a hexagon rotated 30[°] clockwise from the hexagon of a unit cell, and is provided such that the center of the shield region coincides with the center of this hexagon.

Comparing the examples illustrated in FIG. 11 and FIG. 13 regarding how to form shield regions, the example illustrated in FIG. 11 has features that a decrease in the total gate width is readily suppressed, but the shapes of shield trenches 117 in the plan view are likely to be restricted. On the other hand, the examples illustrated in FIG. 13 have features that a decrease in the total gate width is not readily suppressed, but the shapes of shield trenches 117 in the plan view are less restricted. According to the designed shape of shield trench 117, the shape of a shield region in the plan view can be selected.

Thus, in the plan view, vertical MOS transistor 10C periodically includes regions (shield regions) where unit cells are not provided, and the area of each of such regions may be 1+3n(n+1) times or 3×n² times the area of a unit cell (n is an integer of 1 or more).

Furthermore, in a region (a shield region) where unit cells are not provided, shield conductor 115 may be provided up to a position deeper than gate trench 17C.

In such a structure as above, gate trench 17C can be provided in a honeycomb arrangement, and furthermore, can be designed to have a fine dimension to increase the total gate width while increasing the breakdown voltage.

As illustrated in FIGS. 10A and 12A, in the plan view, the three nearest regions where unit cells are not provided (shield regions) may be arranged with the centers thereof being at the positions of the vertices of equilateral triangles within the plane of active region 112.

By arranging shield regions as described above and further providing shield trenches 117, in the plan view, the effect of uniformly reducing the electric field intensity at the tip of gate trench 17C, which is located inside an equilateral triangle, can be achieved by providing shield trench 117 at the vertex position of the equilateral triangle. If the equilateral triangles are tiled with no spacing within the plane of active region 112, the effect of reducing the electric field intensity can be obtained by entire gate trench 17C.

### Embodiment 3

In the following, a description will be given of semiconductor device 1D (vertical MOS transistor 10D (transistor 10D)) according to Embodiment 3, in which some elements are changed from semiconductor device 1 (transistor 10) according to Embodiment 1.

In transistor 10D according to Embodiment 3, in each unit cell, source region 14 and body contact region 18 are changed to source region 14D according to Embodiment 3 and body contact region 18aD according to Embodiment 3.

Here, regarding transistor 10D according to Embodiment 3, the elements similar to those of transistor 10 according to Embodiment 1 are assigned the same reference signs and detailed descriptions thereof are omitted as such elements have already been described, so the description centers on the differences from transistor 10.

### [1. Structure of Semiconductor Device]

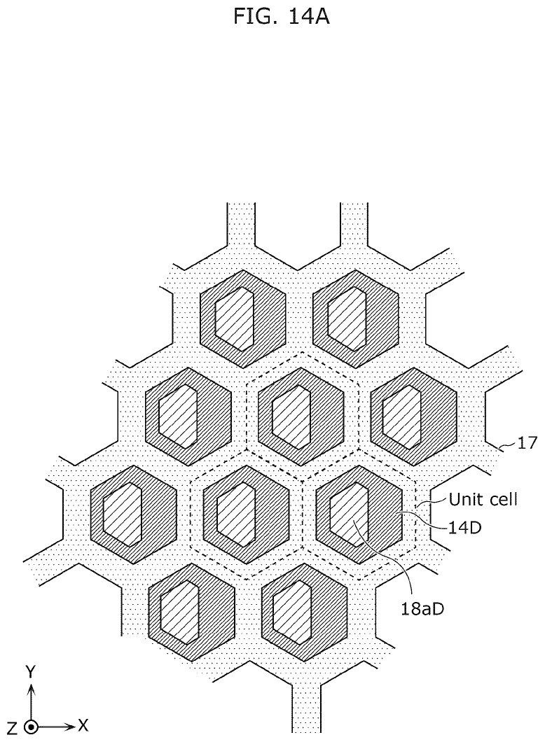

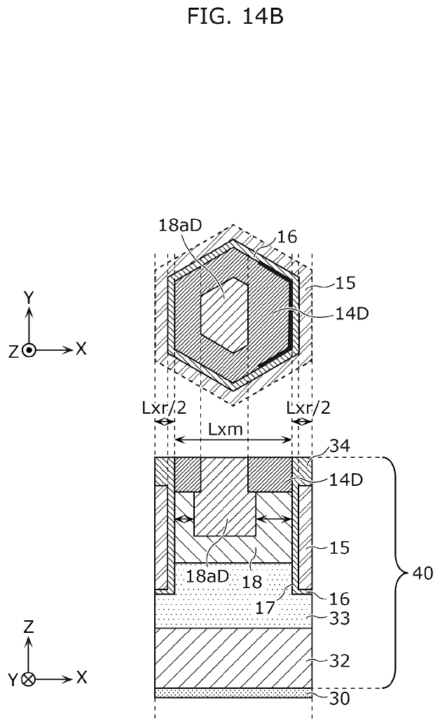

FIG. 14A is a plan schematic diagram illustrating an enlarged portion of the structure of active region 112 of semiconductor device 1D (transistor 10D) according to Embodiment 3. FIG. 14B includes a plan schematic diagram and a cross-sectional schematic diagram of a unit cell of semiconductor device 1D (transistor 10D) according to Embodiment 3. Note that FIG. 14A and FIG. 14B are illustrations excluding source electrode 11, interlayer insulating layer 34 above semiconductor layer 40, and passivation layer 35, to facilitate understanding. Furthermore, interlayer insulating layer 34 inside gate trench 17 is also excluded from the plan schematic diagrams.

As illustrated in the plan schematic diagrams in FIG. 14A and FIG. 14B, in the shape of body contact region 18aD exposed at the upper surface of semiconductor layer 40 in the plan view, on a diagonal line (in the example illustrated in the plan schematic diagram in FIG. 14B, a diagonal line other than the diagonal line parallel to the Y direction) connecting one corner of a unit cell and another corner opposite the one corner on a straight line across the center of the unit cell, the distance between the one corner and body contact region 18aD and the distance between the other corner and body contact region 18aD differ from each other.

As an example, as illustrated in the plan schematic diagram in FIG. 14B, the shape of body contact region 18aD exposed at the upper surface of semiconductor layer 40 in the plan view may be a hexagon not in a similar relation with the hexagon of the unit cell and may not have rotational symmetry of less than 360[°] in a clockwise direction. Alternatively, the shape may be a polygon having a center that does not coincide with the center of the unit cell or may be an ellipse.

Accordingly, in the plan view, the shape of source region 14D exposed at the upper surface of semiconductor layer 40 also has a width that changes irregularly in a direction away from gate trench 17 around the mesa.

As illustrated in the cross-sectional schematic diagram in FIG. 14B, body contact region 18aD is connected to body region 18 located directly thereunder and connects portion 13 of source electrode 11 and body region 18. Body contact region 18aD contains an impurity of the second conductivity type at a higher concentration than the concentration of an impurity of the second conductivity type contained in body region 18.

As illustrated in the cross-sectional schematic diagram in FIG. 14B, the lower surface of body contact region 18aD is located at a position deeper than that of the lower surface of source region 14D, and furthermore, a portion of body contact region 18aD is located directly under source region 14D. As illustrated in the cross-sectional schematic diagram in FIG. 14B, also directly under source region 14D, the distance between body contact region 18aD and gate trench 17 differs between one side and the other side on a diagonal line connecting one corner of the unit cell and another corner opposite the one corner on a straight line across the center of the unit cell in the plan view (in the example illustrated in the plan schematic diagram in FIG. 14B, a diagonal line other than the diagonal line parallel to the Y direction).

The operation of transistor 10D according to Embodiment 3 is the same as that of transistor 10 according to Embodiment 1, so the description is omitted.

### [2. Consideration]

Hereinafter, a description will be given of the effects achieved by semiconductor device 1D (transistor 10D) according to Embodiment 3.

In Embodiment 3, as illustrated in the cross-sectional schematic diagram in FIG. 14B, a first portion where the distance between body contact region 18aD and gate trench 17 directly under source region 14D is relatively small and a second portion where that distance is relatively large are provided inside one unit cell. In the plan view of the plan schematic diagram in FIG. 14B, the perimeter portion of the mesa at the location corresponding to the second portion is schematically shown with a thick line, but the first portion can be made larger than the second portion by adjusting the shape of body contact region 18aD in the plan view and the position at which body contact region 18aD is provided in the plan view.

In the first portion directly under source region 14D where the distance between body contact region 18aD and gate trench 17 is relatively small, a threshold voltage for applying a voltage to gate conductor 15 to form a channel in body region 18 is relatively high. This is because the influence of body contact region 18aD approaching gate trench 17 causes the concentration of an impurity of the second conductivity type to approach an effectively higher state in body region 18 where a channel is formed.

In contrast, in the second portion directly under source region 14D where the distance between body contact region 18aD and gate trench 17 is relatively large, the concentration of an impurity of the second conductivity type in body region 18 where a channel is formed is less influenced by body contact region 18aD. Thus, in the second portion, a threshold voltage for applying a voltage to gate conductor 15 to form a channel in body region 18 is relatively low.

Thus, in transistor 10D according to Embodiment 3, it is possible to provide, within one unit cell, a structure where a portion having a low threshold and a small gate width (a second portion) and a portion having a high threshold and a large gate width (a first portion) are mixed. It will be described that in transistor 10D having such a structure, the tolerance immediately after turning on the transistor can be improved as compared to transistor 10A according to Comparative Example 1 of Embodiment 1.

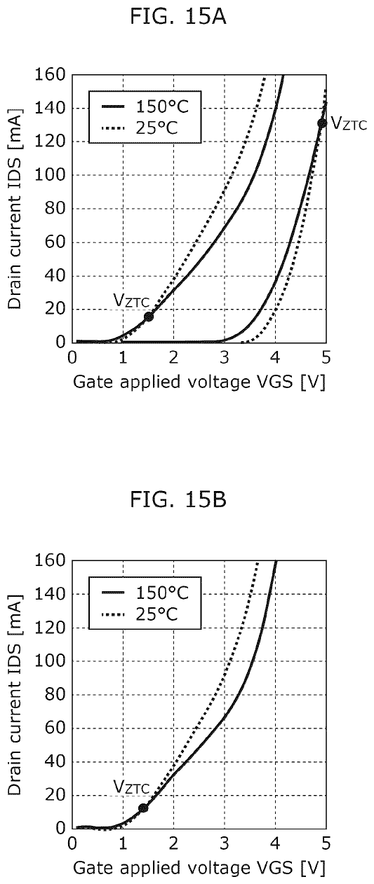

FIG. 15A illustrates gate applied voltage VGS [V] dependence (hereinafter referred to as IDS-VGS dependence) of drain-source current IDS [mA] in a typical semiconductor device (transistor) in a state where a constant voltage is applied between the drain and the source. The horizontal axis represents VGS, and the vertical axis represents IDS.

The left side of FIG. 15A shows calculation results under the assumption of a transistor having a low threshold and a small total gate width, with the dotted line and the solid line representing the IDS-VGS dependence at 25° C. and 150° C., respectively. The right side of FIG. 15A shows calculation results under the assumption of a transistor having a high threshold and a large total gate width, with the dotted line and the solid line representing the IDS-VGS dependence at 25° C. and 150° C., respectively.

In typical transistors, it is known that the temperature coefficient of the IDS-VGS dependence is positive in the range where VGS is low and is negative in the range where VGS is high. Thus, when a transistor is turned on under the condition where VGS is low, the temperature of the transistor increases due to the heat generated by energization and furthermore, current flows through the transistor due to the positive temperature coefficient. Moreover, due to the increase in current, the temperature of the transistor further increases, and because of that, the current even more readily flows. Such thermal runaway (also referred to as positive feedback) may occur.

In FIG. 15A, the plotted black dots are points where the temperature coefficient of the IDS-VGS dependence changes from positive to negative (VGS=V_{ZTC}[V]), in the transistors under the assumed conditions. In the result shown on the left side of FIG. 15A, the black dot is in the range of low VGS, but in the result shown on the right side of FIG. 15A, the black dot is in the range of high VGS. Hence, in the transistor having a high threshold and a large total gate width, V_{ZTC} is high, so thermal runaway tends to readily occur when causing the transistor to operate under a condition where VGS is low, immediately after turning on the transistor.

FIG. 15B illustrates the IDS-VGS dependence of a transistor resulting from mixing the transistors whose IDS-VGS dependencies are shown on the left and right sides of FIG. 15A. That is, the result illustrated in FIG. 15B corresponds to the IDS-VGS dependence exhibited by the structure of semiconductor device 1D (transistor 10D) according to Embodiment 3 illustrated in FIG. 14B.

Looking at the IDS-VGS dependence of semiconductor device 1D (transistor 10D) according to Embodiment 3 illustrated in FIG. 15B, the point where the temperature coefficient of the IDS-VGS dependence changes from positive to negative (VGS=V_{ZTC}) is in the low VGS range, due to the influence by the existence of the second portion. That is, as with transistor 10D, by mixing a portion having a relatively low threshold (a second portion) in a unit cell, the effect of expanding the range of VGS where the temperature coefficient of the IDS-VGS dependence can be made negative can be obtained.

Semiconductor device 1A (Transistor 10A) according to Variation 1 of Embodiment 1 illustrated in FIG. 5 includes body contact region 18aA present even directly under source region 14.

Accordingly, as compared to transistor 10 according to Embodiment 1, transistor 10A is in a state where the threshold is high due to the influence of gate trench 17 and body contact region 18aA being near, and the range where the temperature coefficient of the IDS-VGS dependence is positive is wide.

Thus, as with semiconductor device 1D (transistor 10D) according to Embodiment 3 illustrated in FIG. 14B, the shape of body contact region 18aD exposed at the upper surface of semiconductor layer 40 in the plan view is formed such that, on a diagonal line connecting one corner of the unit cell and another corner opposite the one corner on a straight line across the center of the unit cell, the distance between the one corner and body contact region 18aD and the distance between the other corner and body contact region 18aD differ from each other, and furthermore, the lower surface of body contact region 18aD is located at a position deeper than that of the lower surface of source region 14D, and a portion of body contact region 18aD is located directly under source region 14D. Hence, a portion having a relatively low threshold is provided, and as illustrated in FIG. 15B, the range where the temperature coefficient of the IDS-VGS dependence is negative can be widened. Accordingly, in transistor 10D, as compared to transistor 10A, the tolerance while causing transistor 10D to operate under a condition that VGS is low, immediately after turning on the transistor improves.

Note that also in transistor 10D according to Embodiment 3, a dimensional relation (FIG. 9) described with regard to transistor 10 according to Embodiment 1 may be satisfied. Thus, in transistor 10D, in the plan view, Lxm/3≤Lxr≤Lxm may be satisfied, where Lxr [μm] denotes the width of the gate trench, and Lxm [μm] denotes a distance between parallel portions of the gate trench that face each other.

Although the semiconductor devices according to aspects of the present disclosure have been described above based on Embodiments 1 to 3 and Variations 1 and 2, the present disclosure is not limited to these embodiments and variations. The scope of one or more aspects of the present disclosure may also encompass embodiments resulting from adding, to the embodiments, various modifications that may be conceived by those skilled in the art, and embodiments obtained by combining elements in different embodiments and variations, as long as the resultant embodiments do not depart from the gist of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

A semiconductor device that includes a vertical MOS transistor according to the present application is widely applicable as a device that controls the conduction state of current paths.

1. A semiconductor device comprising:
a vertical metal-oxide semiconductor (MOS) transistor that includes:
a semiconductor substrate of a first conductivity type, the semiconductor substrate containing an impurity at a first concentration;
a low-concentration impurity layer of the first conductivity type, the low-concentration impurity layer being provided above and in contact with the semiconductor substrate and containing an impurity at a second concentration lower than the first concentration of the impurity contained in the semiconductor substrate;
a body region of a second conductivity type different from the first conductivity type, the body region being provided in the low-concentration impurity layer;
a source region of the first conductivity type, the source region being provided in the body region;
a body contact region of the second conductivity type, the body contact region being provided in the body region;
a source electrode connected to the body contact region and the source region;
a gate trench provided from an upper surface of the low-concentration impurity layer and penetrating through the body region to reach a depth up to a portion of the low-concentration impurity layer;
a gate insulating film provided inside the gate trench; and
a gate conductor provided above the gate insulating film and embedded inside the gate trench,
wherein in a plan view of the low-concentration impurity layer, an active region of the vertical MOS transistor includes unit cells repeatedly arranged within a plane of the active region,
in the plan view, each of the unit cells is a hexagon having a perimeter defined along center positions of a width of the gate trench,
in the plan view, in each of the unit cells, the source region in contact with the gate trench along an entire perimeter and the body contact region surrounded by the source region are exposed at the upper surface of the low-concentration impurity layer,
in the plan view, in each of the unit cells, a shape of the body contact region exposed at the upper surface of the low-concentration impurity layer has a center that coincides with a center of the unit cell and rotational symmetry of 60° or less in a clockwise direction,
in the plan view, in each of the unit cells, a shape of the source region exposed at the upper surface of the low-concentration impurity layer has a maximum width in a direction away from the gate trench, on a diagonal line connecting one corner of the unit cell and an other corner opposite the one corner on a straight line across the center of the unit cell, and
in the plan view, Lxm/3≤Lxr≤Lxm is satisfied, where Lxr μm denotes the width of the gate trench, and Lxm μm denotes a distance between parallel portions of the gate trench that face each other.

2. The semiconductor device according to claim 1,
wherein in the plan view, in each of the unit cells, the shape of the body contact region exposed at the upper surface of the low-concentration impurity layer is substantially circular.

3. The semiconductor device according to claim 1,
wherein in the plan view, in each of the unit cells, the shape of the body contact region exposed at the upper surface of the low-concentration impurity layer corresponds to a hexagon rotated 30° clockwise from the hexagon of the unit cell.

4. The semiconductor device according to claim 1,
wherein in the plan view, in each of the unit cells, on the diagonal line, the maximum width of the shape of the source region exposed at the upper surface of the low-concentration impurity layer in the direction away from the gate trench is smaller than a width of the shape of the body contact region exposed at the upper surface of the low-concentration impurity layer.

5. The semiconductor device according to claim 1,
wherein a lower surface of the body contact region is located at a position deeper than a position of a lower surface of the source region, and
a portion of the body contact region is directly under the source region.

6. The semiconductor device according to claim 1,
wherein the following equation is satisfied:
$$Lxr = \frac{\sqrt{3}}{3} \times L x m . \qquad [ Math . 1 ]$$

7. The semiconductor device according to claim 1,
wherein Lxr≤0.15 μm is satisfied, and
in the plan view, the gate conductor includes a portion that terminates without being connected to a gate wiring at a periphery of the active region.

8. The semiconductor device according to claim 1,
wherein in the plan view, the active region periodically includes regions where the unit cells are not provided, and
an area of each of the regions is 1+3n(n+1) times or 3n² times an area of each of the unit cells, where n is an integer of 1 or more.

9. The semiconductor device according to claim 8,
wherein in the plan view, among the regions where the unit cells are not provided, three nearest regions are arranged with centers of the three nearest regions being located at vertices of a regular triangle within the plane of the active region.

10. The semiconductor device according to claim 8,
wherein in each of the regions where the unit cells are not provided, a shield conductor is provided to a depth greater than a depth of the gate trench.

11. A semiconductor device comprising:
a vertical metal-oxide semiconductor (MOS) transistor that includes:
a semiconductor substrate of a first conductivity type, the semiconductor substrate containing an impurity at a first concentration;
a low-concentration impurity layer of the first conductivity type, the low-concentration impurity layer being provided above and in contact with the semiconductor substrate and containing an impurity at a second concentration lower than the first concentration of the impurity contained in the semiconductor substrate;
a body region of a second conductivity type different from the first conductivity type, the body region being provided in the low-concentration impurity layer;
a source region of the first conductivity type, the source region being provided in the body region;
a body contact region of the second conductivity type, the body contact region being provided in the body region;
a source electrode connected to the body contact region and the source region;
a gate trench provided from an upper surface of the low-concentration impurity layer and penetrating through the body region to reach a depth up to a portion of the low-concentration impurity layer;
a gate insulating film provided inside the gate trench; and
a gate conductor provided above the gate insulating film and embedded inside the gate trench,
wherein in a plan view of the low-concentration impurity layer, an active region of the vertical MOS transistor includes unit cells repeatedly arranged within a plane of the active region,
in the plan view, each of the unit cells is a hexagon having a perimeter defined along center positions of a width of the gate trench,
in the plan view, in each of the unit cells, the source region in contact with the gate trench along an entire perimeter and the body contact region surrounded by the source region are exposed at the upper surface of the low-concentration impurity layer,
in the plan view, in each of the unit cells, in a shape of the body contact region exposed at the upper surface of the low-concentration impurity layer, on a diagonal line connecting one corner of the unit cell and an other corner opposite the one corner on a straight line across a center of the unit cell, a distance between the one corner and the body contact region and a distance between the other corner and the body contact region differ from each other,
a lower surface of the body contact region is located at a deeper position than a position of a lower surface of the source region, and
a portion of the body contact region is directly under the source region.

12. The semiconductor device according to claim 11,
wherein in the plan view, Lxm/3≤Lxr≤Lxm is satisfied, where Lxr μm denotes the width of the gate trench and Lxm μm denotes a distance between parallel portions of the gate trench that face each other.
